(19) United States
(12) Patent Application Publication
(10) Pub. No.: US 2024/0234427 A1
(43) Pub. Date: Jul. 11, 2024

(54) ELECTRONIC DEVICE AND MANUFACTURING METHOD THEREOF

(71) Applicant: InnoLux Corporation, Miao-Li County (TW)

(72) Inventors: Yuan-Lin WU, Miao-Li County (TW); Tsung-Han Tsai, Miao-Li County (TW); Kuan-Feng Lee, Miao-Li County (TW)

(73) Assignee: InnoLux Corporation, Miao-Li County (TW)

(21) Appl. No.: 18/391,692

(22) Filed: Dec. 21, 2023

(30) Foreign Application Priority Data
Jan. 6, 2023 (CN) 202310017543.3

(51) Int. Cl. H01L 27/12; H01L 25/16

(52) U.S. Cl. CPC H01L 27/1218; H01L 25/167; H01L 27/1262

(57) ABSTRACT

An electronic device includes a flexible element, a plurality of electronic units disposed on the flexible element, and a first supporting element disposed under the flexible element. The flexible element has a first Young's modulus E1, the first supporting element has a second Young's modulus E2, and the first Young's modulus E1 and the second Young's modulus E2 meet following equation: 100<E2/E1<250.

### BACKGROUND OF THE DISCLOSURE

### 1. Field of the Disclosure

The present disclosure relates to an electronic device and the manufacturing method thereof, and more particularly to a stretchable electronic device and the manufacturing method thereof.

### 2. Description of the Prior Art

Stretchable electronic devices can be adhered to any suitable surface (for example, curved surface), thereby increasing the applications of the stretchable electronic devices. However, the possibility of breaking of the layers (such as substrate) of the stretchable electronic device may be great during the manufacturing process or deformation process of the stretchable electronic device, thereby affecting the lifespan of the stretchable electronic device. Therefore, to improve the design of the stretchable electronic device to reduce the possibility of breaking of the device is still an important issue in the present field.

### SUMMARY OF THE DISCLOSURE

The present disclosure aims at providing an electronic device and the manufacturing method thereof.

In some embodiments, an electronic device is provided by the present disclosure. The electronic device includes a flexible element, a plurality of electronic units disposed on the flexible element, and a first supporting element disposed under the flexible element. The flexible element has a first Young's modulus E1, the first supporting element has a second Young's modulus E2, and the first Young's modulus E1 and the second Young's modulus E2 meet following equation:

100<E2/E1<250.

In some embodiments, an electronic device is provided by the present disclosure. The electronic device includes a flexible structure having a flexible element and a plurality of openings, an electronic unit disposed on the flexible element, and a supporting structure disposed under the flexible structure. The supporting structure has a plurality of supporting elements overlapped with a portion of the flexible element and a space overlapped with the plurality of openings. An outline of at least one of the supporting elements has a curved shape.

In some embodiments, a manufacturing method of an electronic device is provided by the present disclosure. The method includes providing a supporting layer, forming a flexible layer on the supporting layer, forming a plurality of electronic units on the flexible layer, patterning the flexible layer to form a flexible structure, wherein the flexible structure has a flexible element and a plurality of openings, and patterning the supporting layer to form a supporting structure after the step of patterning the flexible layer, wherein the supporting structure has a plurality of supporting elements and a space.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1 schematically illustrates a cross-sectional view of an electronic device according to a first embodiment of the present disclosure.

FIG. 2 schematically illustrates a top view of a flexible structure of the electronic device according to the first embodiment of the present disclosure.

FIG. 3 schematically illustrates a top view of a supporting structure of the electronic device according to the first embodiment of the present disclosure.

FIG. 4 schematically illustrates the samples of a flexible element and a supporting element of the electronic device according to the first embodiment of the present disclosure for measuring the Young's modulus.

FIG. 5 schematically illustrates a top view of a buffer layer of the electronic device according to the first embodiment of the present disclosure.

FIG. 6 schematically illustrates a cross-sectional view of an electronic device according to a second embodiment of the present disclosure.

FIG. 7, FIG. 8 and FIG. 9 schematically illustrate the manufacturing process of an electronic device according to a third embodiment of the present disclosure.

FIG. 10 and FIG. 11 schematically illustrate the manufacturing process of an electronic device according to a variant embodiment of the third embodiment of the present disclosure.

### DETAILED DESCRIPTION

The present disclosure may be understood by reference to the following detailed description, taken in conjunction with the drawings as described below. It is noted that, for purposes of illustrative clarity and being easily understood by the readers, various drawings of this disclosure show a portion of the electronic device, and certain elements in various drawings may not be drawn to scale. In addition, the number and dimension of each element shown in drawings are only illustrative and are not intended to limit the scope of the present disclosure.

Certain terms s are used throughout the description and following claims to refer to particular elements. As one skilled in the art will understand, electronic equipment manufacturers may refer to an element by different names. This document does not intend to distinguish between elements that differ in name but not function.

In the following description and in the claims, the terms “include”, “comprise” and “have” are used in an open-ended fashion, and thus should be interpreted to mean “include, but not limited to . . . ”.

It will be understood that when an element or layer is referred to as being “disposed on” or “connected to” another element or layer, it can be directly on or directly connected to the other element or layer, or intervening elements or layers may be presented (indirectly). In contrast, when an element is referred to as being “directly on” or “directly connected to” another element or layer, there are no intervening elements or layers presented. When an element or a layer is referred to as being “electrically connected” to another element or layer, it can be a direct electrical connection or an indirect electrical connection. The electrical connection or coupling described in the present disclosure may refer to a direct connection or an indirect connection. In the case of a direct connection, the ends of the elements on two circuits are directly connected or connected to each other by a conductor segment. In the case of an indirect connection, switches, diodes, capacitors, inductors, resistors, other suitable elements or combinations of the above elements may be included between the ends of the elements on two circuits, but not limited thereto.

Although terms such as first, second, third, etc., may be used to describe diverse constituent elements, such constituent elements are not limited by the terms. The terms are used only to discriminate a constituent element from other constituent elements in the specification. The claims may not use the same terms, but instead may use the terms first, second, third, etc. with respect to the order in which an element is claimed. Accordingly, in the following description, a first constituent element may be a second constituent element in a claim.

In the present disclosure, the thickness, length and width may be measured through optical microscope, and the thickness or width may be measured through the cross-sectional view in the electron microscope, but not limited thereto.

In addition, any two values or directions used for comparison may have certain errors. In addition, the terms “equal to”, “equal”, “the same”, “approximately” or “substantially” are generally interpreted as being within +20%, +10%, +5%, +3%, +2%, +1%, or +0.5% of the given value.

In addition, the terms “the given range is from a first value to a second value” or “the given range is located between a first value and a second value” represents that the given range includes the first value, the second value and other values there between.

If a first direction is said to be perpendicular to a second direction, the included angle between the first direction and the second direction may be located between 80 to 100 degrees. If a first direction is said to be parallel to a second direction, the included angle between the first direction and the second direction may be located between 0 to 10 degrees.

Unless it is additionally defined, all terms (including technical and scientific terms) used herein have the same meaning as commonly understood by those ordinary skilled in the art. It can be understood that these terms that are defined in commonly used dictionaries should be interpreted as having meanings consistent with the relevant art and the background or content of the present disclosure, and should not be interpreted in an idealized or overly formal manner, unless it is specifically defined in the embodiments of the present disclosure.

It should be noted that the technical features in different embodiments described in the following can be replaced, recombined, or mixed with one another to constitute another embodiment without departing from the spirit of the present disclosure.

The electronic device of the present disclosure may include a display device, a sensing device, a back-light device, an antenna device, a tiled device or other suitable electronic devices, but not limited thereto. The electronic device may be a foldable electronic device, a flexible electronic device or a stretchable electronic device. For example, the electronic device of the present disclosure may include a flexible electronic device. The display device may for example be applied to laptops, common displays, tiled displays, vehicle displays, touch displays, televisions, monitors, smart phones, tablets, light source modules, lighting devices or electronic devices applied to the products mentioned above, but not limited thereto. The sensing device may include a biosensor, a touch sensor, a fingerprint sensor, other suitable sensors or combinations of the above-mentioned sensors. The antenna device may for example include a liquid crystal antenna device, but not limited thereto. The tiled device may for example include a tiled display device or a tiled antenna device, but not limited thereto. The outline of the electronic device may be a rectangle, a circle, a polygon, a shape with curved edge or other suitable shapes. The electronic device may include electronic units, wherein the electronic units may include passive elements and active elements, such as capacitor, resistor, inductor, diode, transistor, sensor, and the like. The diode may include a light emitting diode or a photo diode. The light emitting diode may for example include organic light emitting diode (OLED) or inorganic light emitting diode. The inorganic light emitting diode may for example include mini light emitting diode (mini LED), micro light emitting diode (micro LED) or quantum dot light emitting diode (QLED), but not limited thereto. It should be noted that the electronic device of the present disclosure may be combinations of the above-mentioned devices, but not limited thereto.

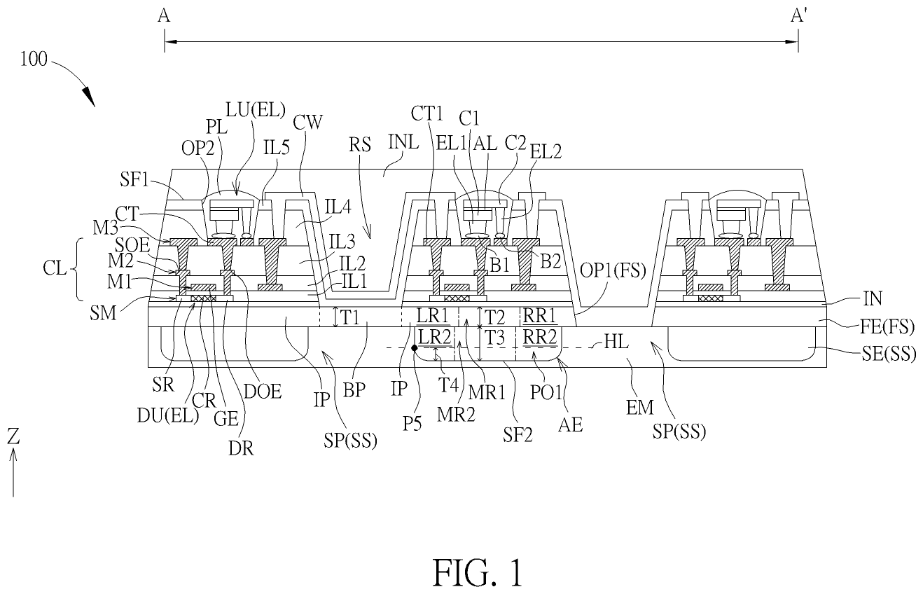

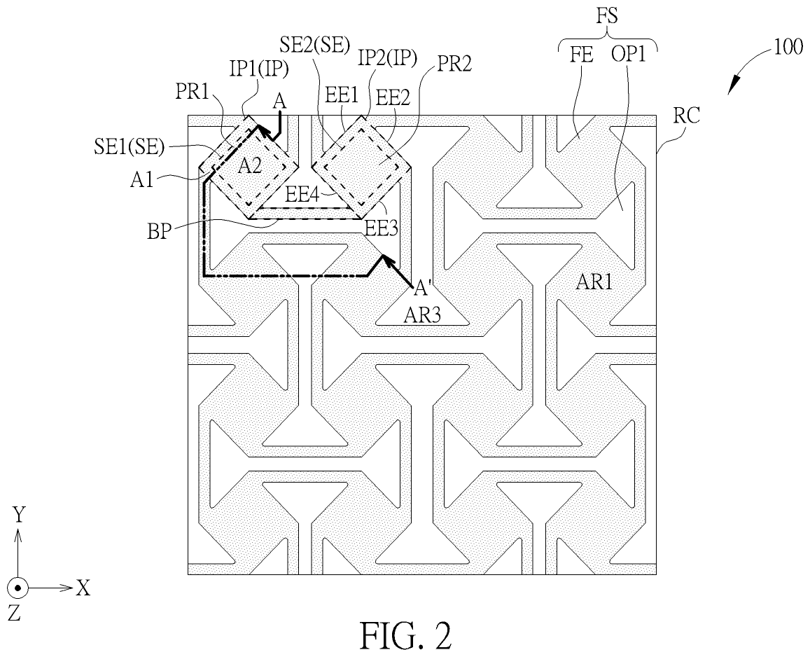

Referring to FIG. 1 and FIG. 2, FIG. 1 schematically illustrates a cross-sectional view of an electronic device according to a first embodiment of the present disclosure, and FIG. 2 schematically illustrates a top view of a flexible structure of the electronic device according to the first embodiment of the present disclosure. According to the present embodiment, the electronic device 100 includes a flexible structure FS, a plurality of electronic units EL and a supporting structure SS, wherein the electronic units EL are disposed on the flexible structure FS, and the supporting structure SS is disposed under the flexible structure FS. The elements and/or the layers included in the electronic device 100 will be detailed in the following.

According to the present embodiment, the flexible structure FS includes a flexible element FE and a plurality of openings OP1 (as shown in FIG. 2) in the flexible element FE. In order to simplify the figure, FIG. 1 just exemplarily shows an opening OP1 of the flexible structure FS, but the present embodiment is not limited thereto. The flexible element FE may be formed by forming the openings OP1 in an entire material layer of the flexible element FE (that is, the flexible layer FL shown in FIG. 8, which will be named as the flexible layer in the following, and will not be redundantly described). In other words, the flexible element FE may be a patterned element formed through a patterning process, wherein the patterning process includes forming the plurality of openings OP1. In the present embodiment, the flexible element FE may be a continuous element, and the openings OP1 may be independent and separated from each other, but not limited thereto. The flexible element FE may include a flexible substrate or at least partially include a flexible substrate for supporting the elements and/or the layers disposed thereon. The term “flexible” mentioned here represents that being curved, folded, rolled, stretched or deformed in other ways. For example, the flexible element FE may include a stretchable substrate, but not limited thereto. In other words, the flexible element FE may be a patterned stretchable substrate. The material of the flexible element FE may include polyimide (PI), polycarbonate (PC), polyethylene terephthalate (PET), other suitable materials or combinations of the above-mentioned materials. It should be noted that although the flexible element FE shown in FIG. 1 is a single layer, the present embodiment is not limited thereto. In some embodiments, the flexible element FE may include a multi-layer structure.

According to the present embodiment, the flexible element FE may include a plurality of island portions IP and a plurality of bridge portions BP, wherein at least one of the plurality of bridge portions BP may connect two adjacent island portions IP. For example, as shown in FIG. 2, the flexible element FE may include a first island portion IP1, a second island portion IP2 adjacent to the first island portion IP1, and a bridge portion BP connecting the first island portion IP1 and the second island portion IP2, but not limited thereto. In other words, an island portion IP may connect to at least one bridge portion BP, thereby being connected to other island portion (s) IP through the at least one bridge portion BP to which the island portion IP connects. In the present embodiment, the edge of the region of the island portion IP may for example be defined through the positions where the width of the flexible element FE start changing, but not limited thereto. For example, in FIG. 2, the width of the flexible element FE would start changing (for example, the width would decrease) at an edge EE1, an edge EE2, an edge EE3 and an edge EE4, and the region enclosed by the edge EE1, the edge EE2, the edge EE3 and the edge EE4 may be defined as the region of the island portion IP. In other embodiments, the region of the island portion IP may be defined through other suitable ways. After the regions of the island portions IP are defined, other portions of the flexible element FE except for the island portions IP may be defined as the bridge portions BP.

According to the present embodiment, the island portion IP may be configured so that the electronic unit EL can be disposed thereon. In other words, the electronic units EL of the electronic device 100 may be disposed corresponding to the island portions IP and located on the island portions IP. “The electronic units EL are disposed corresponding to the island portions IP” mentioned here may represent that the electronic units EL may at least partially overlap the island portions IP in a top view direction of the electronic device 100, but not limited thereto. In the present embodiment, the electronic units EL may include light emitting units (such as the light emitting units LU shown in FIG. 1) or other active elements, such as the channel regions of the thin film transistors (for example, the driving unit DU shown in FIG. 1) in the circuit layer (for example, the circuit layer CL shown in FIG. 1), but not limited thereto. In other words, the light emitting units LU or at least the channel regions of the thin film transistors in the circuit layer CL may be disposed on the island portions IP. The bridge portion BP may be configured to change the distance between the adjacent island portions IP to which it connects. For example, when the electronic device 100 is deformed (for example, being stretched), the bridge portion BP may be deformed, such that the size (such as length) of the bridge portion BP is changed due to deformation of the electronic device 100, thereby changing the distance between the island portions IP, but not limited thereto. Or, when the electronic device 100 is deformed (for example, being stretched), the included angles between the bridge portion BP and the island portions IP adjacent to the bridge portion BP may be changed, and the size and the shape of the opening OP1 may thereby be changed, for example, the size of the opening OP1 may increase, such that the distance between the adjacent island portions IP may increase, but not limited thereto. In another aspect, through different pattern designs, the bridge portions BP with different sizes may be designed, thereby changing the distance between the adjacent island portions IP. In other words, the island portions IP may provide the supporting function of the electronic units EL disposed thereon, and the bridge portions BP may provide the stretching function of the flexible element FE. In the present embodiment, the shape of the island portion IP may be a diamond or a rectangular, and the bridge portion BP may be string-shaped, but not limited thereto. In some embodiments, the shape of the island portion IP may be a circle, an oval, a polygon or other suitable shapes.

As mentioned above, the electronic units EL may be disposed corresponding to the island portions IP of the flexible element FE. In other words, the electronic units EL may be disposed on the flexible element FE of the flexible structure FS. According to the present embodiment, the electronic units EL may include any working unit, driving units for driving the working unit and/or other suitable electronic elements in the electronic device 100. When the electronic device 100 includes a display device, the working unit may include the light emitting units; and when the electronic device 100 includes a sensing device, the working unit may include the sensing units, but not limited thereto. In some embodiments, the electronic device 100 may include more than one kind of working units (for example, including both the light emitting units and the sensing units, but not limited thereto), according to the demands of the design of the product. In the present embodiment, the electronic device 100 may include a display device, and the electronic units EL may for example include the light emitting units LU, the driving units DU and/or other suitable electronic elements, but not limited thereto. The driving units DU of the present embodiment may be the driving units for driving the light emitting units LU or driving other suitable electronic elements of the electronic device 100. The structure of the electronic unit EL of the electronic device 100 of the present embodiment will be detailed in the following.

As shown in FIG. 1, the electronic device 100 may include a circuit layer CL disposed on the flexible element FE and light emitting units LU disposed on the circuit layer CL. According to the present embodiment, the circuit layer CL may be patterned and disposed on the island portions IP of the flexible element FE, but not limited thereto. Specifically, an entire circuit layer CL may be disposed at first, and then the portion of the circuit layer CL not corresponding to the island portions IP may be removed to form the patterned circuit layer CL. Since the circuit layer CL may not be disposed corresponding to the bridge portions BP, the thickness of the portion of the electronic device 100 corresponding to the island portions IP may for example be greater than the thickness of the portion of the electronic device 100 corresponding to the bridge portions BP, and the electronic device 100 may include recess regions RS corresponding to the bridge portions BP, as shown in FIG. 1. The circuit layer CL may include various kinds of wires, circuits, active elements and/or passive elements that can be applied to the electronic device 100. For example, the circuit layer CL may include driving units DU, wherein the driving units DU may be electrically connected to any suitable electronic element in the electronic device 100. For example, a driving unit DU may be electrically connected to a light emitting unit LU, thereby controlling the light emission of the light emitting unit LU to which the driving unit DU connects, but not limited thereto. The driving units DU may for example include thin film transistors (TFT), but not limited thereto. Specifically, the circuit layer CL may include a semiconductor layer SM, a conductive layer M1, a conductive layer M2 and a conductive layer M3, wherein the semiconductor layer SM may form the channel region CR, the source region SR and the drain region DR of the driving unit DU, and the conductive layer M1 may form the gate electrode GE of the driving unit DU. The conductive layer M2 may be located on the conductive layer M1, and the conductive layer M2 may for example form the source electrode SOE and the drain electrode DOE respectively be electrically connected to the source region SR and the drain region DR. The conductive layer M3 may be located on the conductive layer M2, and the conductive layer M3 may for example form the contacts CT electrically connected to the source electrode SOE and the drain electrode DOE, but not limited thereto. The semiconductor layer SM may include semiconductor materials. The semiconductor materials may for example include silicon or metal oxides, such as low temperature polysilicon (LTPS) semiconductor, amorphous silicon (a-Si) semiconductor, low temperature polysilicon oxide (LTPO), indium gallium zinc oxide (IGZO) semiconductor, but not limited thereto. The conductive layer M1, the conductive layer M2 and the conductive layer M3 may include any suitable conductive material, such as metal materials, but not limited thereto. As shown in FIG. 1, the circuit layer CL may further include an insulating layer IL1 located between the semiconductor layer SM and the conductive layer M1, an insulating layer IL2 located between the conductive layer M1 and the conductive layer M2, and an insulating layer IL3 located between the conductive layer M2 and the conductive layer M3. The insulating layer IL1, the insulating layer IL2 and the insulating layer IL3 may include any suitable insulating material, such as organic insulating materials or inorganic insulating materials. In some embodiments, the organic insulating materials may include epoxy resin, acrylic resin (such as polymethylmetacrylate (PMMA)), benzocyclobutene (BCB), polyimide, polyester, polydimethylsiloxane (PDMS), other suitable protecting materials or combinations of the above-mentioned materials, but not limited thereto. In some embodiments, the inorganic insulating materials may include silicon nitride, silicon oxide, silicon oxynitride, aluminum oxide, other suitable protecting materials or combinations of the above-mentioned materials, but not limited thereto. The insulating materials mentioned in the following may refer to the above-mentioned materials, and will not be redundantly described. The insulating layer IL1 may for example be the gate insulating layer of the driving unit DU. It should be noted that the structure of the circuit layer CL shown in FIG. 1 is exemplary, and the present embodiment is not limited thereto.

According to the present embodiment, the light emitting units LU disposed on the circuit layer CL may correspond to the island portions IP. The light emitting units LU may for example include light emitting diodes, but not limited thereto. The light emitting diode may for example include an organic light emitting diode (OLED) or an inorganic light emitting diode, and the inorganic light emitting diode may for example include mini light emitting diode (mini LED), micro light emitting diode (micro LED) or quantum dot light emitting diode (QLED), but not limited thereto. In FIG. 1, the light emitting unit LU including the inorganic light emitting diode is taken as an example to describe the structure of the light emitting unit LU, but the present embodiment is not limited thereto. Specifically, the electronic device 100 may further include an insulating layer IL4 and an insulating layer IL5 disposed on the circuit layer CL, wherein the insulating layer IL4 may cover the conductive layer M3 of the circuit layer CL, and the insulating layer IL5 may be disposed on the insulating layer IL4, but not limited thereto. In the present embodiment, the insulating layer IL4 and the insulating layer IL5 may be disposed corresponding to the island portions IP. The insulating layer IL4 and the insulating layer IL5 may include any suitable insulating material. According to the present embodiment, a portion of the insulating layer IL4 and a portion of the insulating layer IL5 may be removed to form at least one opening OP2, wherein the opening OP2 may expose at least a portion of the conductive layer M3 of the circuit layer CL, and the light emitting unit LU may be disposed in the opening OP2 and be electrically connected to the driving unit DU. Specifically, the light emitting unit LU may include a semiconductor C1, a semiconductor C2, an active layer AL located between the semiconductor C1 and the semiconductor C2, an electrode EL1 connected to the semiconductor C1, and an electrode EL2 connected to the semiconductor C2, wherein the electrode EL1 and the electrode EL2 may respectively be electrically connected to the conductive layer M3 exposed by the opening OP2 through a bonding material B1 and a bonding material B2, such that the light emitting unit LU may be electrically connected to the driving unit DU or other electronic elements through the contacts CT formed of the conductive layer M3. The bonding material B1 and the bonding material B2 for example include anisotropic conductive film (ACF), tin (Sn), gold-tin alloy, silver glue, other suitable materials or combinations of the above-mentioned materials, but not limited thereto. In the present embodiment, one of the light emitting units LU may be disposed on one of the island portions IP, but not limited thereto. In other embodiments, a plurality of light emitting units LU may be disposed on one of the island portions IP. In addition, the electronic device 100 may further include a protecting layer PL, wherein the protecting layer PL may be disposed on the light emitting units LU and cover the light emitting units LU to provide protection, but not limited thereto.

It should be noted that although the electronic unit EL of the present embodiment may be the driving unit DU, the light emitting unit LU and/or other suitable electronic elements, the present disclosure is not limited thereto. In other embodiments, the electronic unit EL may include any suitable electronic element according to the demands of the design of the product.

In addition, in the present embodiment, the insulating layer IL5 may extend on the bridge portions BP of the flexible element FE and may be filled into the openings OP1 of the flexible structure FS, but not limited thereto. In the present embodiment, the insulating layer IL5 may extend into the recess regions RS corresponding to the bridge portions BP and cover the bridge portions BP of the flexible element FE. Therefore, abnormal condition of the electronic elements (such as the driving unit DU or the light emitting unit LU) in the electronic device 100 due to being affected by moisture or oxygen from the outside may be reduced. In some embodiments, the insulating layer IL5 may be disposed on the island portions IP, and the insulating layer IL5 may not extend on the bridge portion BP and/or not be filled into the opening OP1. In some embodiments, the electronic device 100 may not include the insulating layer IL5.

According to the present embodiment, the electronic device 100 may include at least one conductive wire CW, wherein the conductive wire CW may be disposed on the bridge portion BP and extend on the bridge portion BP. In addition, two ends of the conductive wire CW may respectively be located on an island portion IP and another island portion IP adjacent to the island portion IP, and the two ends of the conductive wire CW may respectively be electrically connected to the electronic units EL on the two island portions IP. Specifically, as shown in FIG. 1, two ends of the conductive wire CW may respectively be located on the surfaces SF1 of the insulating layer IL5 on two adjacent island portions IP, and the conductive wire CW may extend into the recess region RS corresponding to the bridge portion BP and extend on the bridge portion BP, but not limited thereto. Since the insulating layer IL5 of the present embodiment may extend on the bridge portions BP, the conductive wire CW may be disposed on the insulating layer IL5, but not limited thereto. In some embodiments, when the insulating layer IL5 is not disposed corresponding to the bridge portion BP, or the electronic device 100 does not include the insulating layer IL5, the conductive wire CW may contact the bridge portion BP, that is, the conductive wire CW may contact the flexible element FE. Since the conductive wire CW may electrically connect the electronic units EL on different island portions IP, electrical signals may be transmitted between the electronic units EL on different island portions IP through the conductive wire CW. Specifically, two ends of the conductive wire CW may respectively extend on two adjacent island portions IP and penetrate the insulating layer IL5 and the insulating layer IL4 to be electrically connected to the contacts CT1, and the two ends of the conductive wire CW may respectively be electrically connected to the active elements (such as the driving units DU) on the two adjacent island portions through the contacts CT1, such that the conductive wire CW may electrically connect the driving units DU on different island portions IP, but not limited thereto. The contacts CT1 may for example be formed of the conductive layer M3, but not limited thereto. The conductive wire CW may include any suitable conductive material, such as metal materials, but not limited thereto.

As shown in FIG. 1, the electronic device 100 may optionally include an insulating layer IN disposed between the flexible element FE and the circuit layer CL, wherein the insulating layer IN may be disposed corresponding to the island portions IP. The insulating layer IN may for example serve as the buffer layer, but not limited thereto. In addition, the electronic device 100 may further include an insulating layer INL, wherein the insulating layer INL may be used to encapsulate the layers and the electronic elements between the insulating layer INL and the flexible element FE (such as the electronic units EL, the conductive wires CW, and the like) to provide protection, but not limited thereto. The insulating layer IN and the insulating layer INL may include any suitable insulating material.

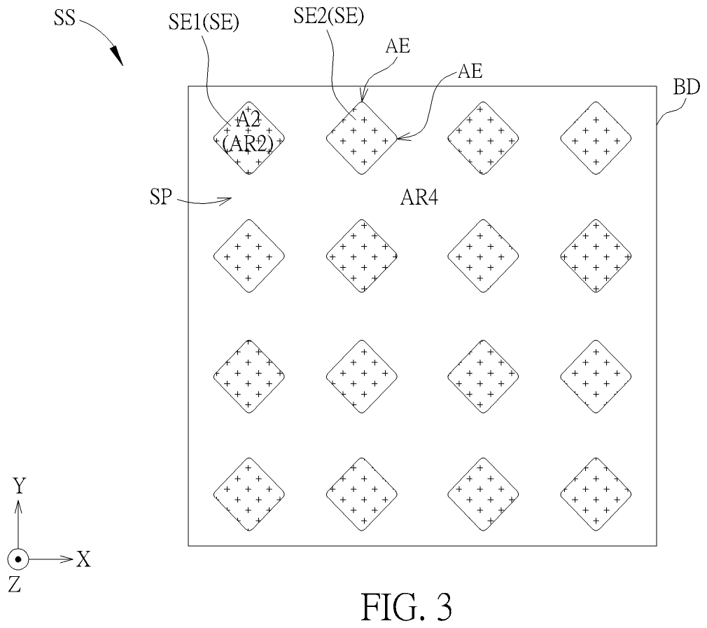

Referring to FIG. 3 as well as FIG. 1 and FIG. 2, FIG. 3 schematically illustrates a top view of a supporting structure of the electronic device according to the first embodiment of the present disclosure. According to the present embodiment, the supporting structure SS may be disposed under the flexible structure FS, and there is no other layer between the supporting structure SS and the flexible structure FS, that is, the supporting structure SS and the flexible structure FS are directly in contact with each other, but not limited thereto. The supporting structure SS may include a plurality of supporting elements SE and a space SP. The supporting elements SE may be formed by forming the space SP in an entire material layer of the supporting elements SE (that is, the supporting layer SL shown in FIG. 8, which will be named as the supporting layer in the following, and will not be redundantly described). In other words, the supporting elements SE may be the patterned elements formed through a patterning process, wherein the patterning process includes forming the space SP. The supporting elements SE may serve as the supporting substrate for providing support to the layers and/or the elements disposed thereon. The supporting elements SE may include rigid materials, such as glass, but not limited thereto. In the present embodiment, the supporting elements SE may respectively be disposed corresponding to the island portions IP of the flexible element FE. Specifically, one of the supporting elements SE may be disposed corresponding to one of the island portions IP and located under the one of the island portions IP. In other words, the supporting elements SE may be disposed under the flexible element FE. “The supporting element SE is disposed corresponding to the island portion IP” mentioned above may represent that the supporting element SE is overlapped with or at least partially overlapped with the island portion IP to which the supporting element SE correspond in the top view direction of the electronic device 100. In other words, each of the supporting elements SE may respectively be overlapped with a portion of the flexible element FE (that is, the island portions IP corresponding to the supporting elements SE). The supporting elements SE may be the elements which are independent and separated from each other, and the space SP may be continuous and located between two adjacent supporting elements SE. For example, as shown in FIG. 2 and FIG. 3, the supporting structure SS may include a first supporting element SE1 and a second supporting element SE2, the first supporting element SE1 is disposed under the flexible element FE (or in other words, the first supporting element SE1 is disposed under a first island portion IP1 of the flexible element FE), and the second supporting element SE2 is disposed under the flexible element FE (or in other words, the second supporting element SE2 is disposed under a second island portion IP2 of the flexible element FE), wherein the space SP may be located between the first supporting element SE1 and the second supporting element SE2. In other words, the first supporting element SE1 may be overlapped with the first island portion IP1, and the second supporting element SE2 may be overlapped with the second island portion IP2. The condition that the first supporting element SE1 and the second supporting element SE2 are respectively overlapped with the first island portion IP1 and the second island portion IP2 is shown by the dotted lines in FIG. 2, and the corresponding condition of other supporting elements SE and island portions IP may refer to the contents mentioned above, which is not shown in FIG. 2.

According to the present embodiment, the space SP of the supporting structure SS may be formed by removing a portion of the supporting layer during the patterning process of the supporting layer. In other words, the region of the space SP may be defined by the removed portion of the supporting layer. In the present embodiment, the space SP may have a border BD, wherein the border BD may be defined through the outer edges of the flexible element FE, but not limited thereto. Specifically, as shown in FIG. 2, a minimum rectangle RC enclosed by the connection lines of the outer edges of the flexible element FE may be defined at first, and the sides of the minimum rectangle RC may correspond to the border BD of the space SP of the supporting structure SS. The minimum rectangle RC may for example be defined when the flexible element FE is not stretched. In other words, the border BD of the space SP may coincide the four sides of the minimum rectangle RC enclosed by the connection lines of the outer edges of the flexible element FE. After the border BD of the space SP is defined, the region in the border BD except for the region occupied by the supporting elements SE may be defined as the region of the space SP. In some embodiments, since the space SP is formed by removing a portion of the supporting layer, the border BD of the space SP may be the outer edges of the supporting layer. As shown in FIG. 1 to FIG. 3, the supporting elements SE may be disposed corresponding to the island portions IP of the flexible element FE, and the space SP may correspond to the openings OP1 and the bridge portions BP of the flexible structure FS. In other words, the space SP may be overlapped with the openings OP1 in the top view direction of the electronic device 100. In addition, the space SP may further correspond to the bridge portions BP of the flexible element FE, or in other words, the space SP may be overlapped with the bridge portions BP. In other words, the space SP of the supporting structure SS may at least partially be overlapped with the flexible element FE of the flexible structure FS. In summary, the electronic device 100 may include the supporting structure SS disposed under the flexible structure FS, wherein the supporting structure SS may be formed by patterning the supporting layer, and the supporting structure SS includes the supporting elements SE corresponding to the island portions IP of the flexible element FE and the space SP corresponding to the bridge portions BP of the flexible element FE and the openings OP1 of the flexible structure FS.

According to the present embodiment, since the supporting elements SE may be disposed corresponding to the island portions IP of the flexible element FE, the supporting elements SE may provide support to the island portions IP disposed thereon, thereby providing support to the electronic elements (such as electronic units EL, conductive wires CW, and the like) disposed on the island portions IP. In other words, the support to the electronic elements may be improved through the supporting elements SE, thereby improving the reliability or yield of the electronic device 100. In addition, since the supporting structure SS may include the space SP corresponding to the openings OP1 and/or the bridge portions BP of the flexible element FE, the influence of the supporting structure SS on the flexibility of the electronic device 100 may be reduced. Moreover, since the supporting structure SS may be formed by patterning the supporting layer, the manufacturing process of the electronic device 100 (will be detailed in the following) may not include the step of peeling the supporting layer from the flexible element FE.

Specifically, in the manufacturing process of the electronic device 100, the supporting layer may be disposed under the flexible structure FS as the carrier substrate, wherein the supporting layer may be patterned to form the supporting structure SS of the electronic device 100, and the supporting layer is not removed from the electronic device 100. Therefore, the damage to the flexible element FE or the breakage of the flexible element FE occurred in the peeling process of the supporting layer may be avoided, thereby improving the yield of the electronic device 100.

According to the present embodiment, the flexible element FE has a first Young's modulus E1, and the supporting elements SE (for example, the first supporting element SE1 and the second supporting element SE2) have a second Young's modulus E2, wherein the first Young's modulus E1 is less than the second Young's modulus E2, and the first Young's modulus E1 and the second Young's modulus E2 meet the following equation (1):

$$100 < E 2 / E 1 < 250 \qquad ( 1 )$$

Specifically, a material having the first Young's modulus E1 may be selected as the material of the flexible layer, and the flexible layer may be patterned to form the flexible element FE, in addition, a material having the second Young's modulus E2 may be selected as the material of the supporting layer, and the supporting layer may be patterned to form the supporting elements SE. In some embodiments, the ratio of the second Young's modulus E2 to the first Young's modulus E1 may be between 105 and 245 (that is, 105<E2/E1<245). In some embodiments, the ratio of the second Young's modulus E2 to the first Young's modulus E1 may be between 110 and 240 (that is, 110<E2/E1<240). The first Young's modulus E1 of the flexible element FE and the second Young's modulus E2 of the supporting elements SE may be obtained by looking up tables, but not limited thereto. In other words, the materials of the flexible element FE and the supporting elements SE may be selected by looking up tables. The following table 1 shows the Young's modulus of multiple materials.

TABLE 1

| material | Young's modulus (GPa) |
|---|---|
| rubber | 0.01-0.1 |
| low density polyethylene (LDPE) | 0.2 |
| polypropylene | 1.5-2 |
| polyethylene terephthalate | 2-2.5 |
| polystyrene | 3-3.5 |
| nylon | 2-4 |
| oak | 11 |
| high-strength concrete | 30 |
| magnesium | 45 |
| glass | 71.7 |

For example, any suitable material having the Young's modulus (that is, the first Young's modulus E1) between 0.3 GPa and 0.6 GPa may be selected as the material of the flexible element FE, and glass may be selected as the material of the supporting elements SE, that is, the second Young's modulus E2 may be 71.7 GPa, but not limited thereto. In other embodiments, the flexible element FE and the supporting elements SE may include any suitable material, such that the first Young's modulus E1 and the second Young's modulus E2 meet the equation (1) mentioned above.

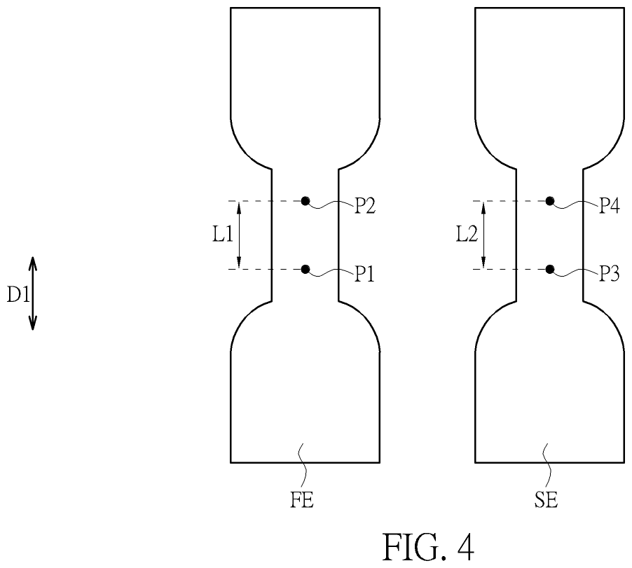

Referring to FIG. 4, FIG. 4 schematically illustrates the samples of a flexible element and a supporting element of the electronic device according to the first embodiment of the present disclosure for measuring the Young's modulus. In the present embodiment, the first Young's modulus E1 and the second Young's modulus E2 may be obtained through measurement. The measuring method of the first Young's modulus E1 and the second Young's modulus E2 will be detailed in the following.

The first Young's modulus E1 and the second Young's modulus E2 can be measured by tensile testing machine, universal testing machine, tension tester (for example, product model 5565, INSTRON CORPORATION), or other suitable equipment. In addition, the measuring method of the first Young's modulus E1 and the second Young's modulus E2 may be based on the ASTM D882 method formulated by ASTM (American Society for Testing and Materials) or other suitable measuring standards.

Before measuring the first Young's modulus E1 and the second Young's modulus E2, the flexible element FE and the supporting element SE may respectively be cut into the samples with the shape shown in FIG. 4, and specific points may be marked on the samples (for example, as shown in FIG. 4, the point P1 and the point P2 on the flexible element FE, and the point P3 and the point P4 on the supporting element SE). It should be noted that the shapes of the samples and the positions of the point P1, the point P2, the point P3 and the point P4 shown in FIG. 4 are exemplary, and the present disclosure is not limited thereto.

After the elements are cut into the samples, the clamps of the testing machine may respectively clamp both sides of the sample in the direction D1, and the samples may be stretched. The change of the distance (such as distance L1) between the point P1 and the point P2 and the change of the distance (such as the distance L2) between the point P3 and the point P4 can be recognized through images, and the first Young's modulus E1 and the second Young's modulus E2 may be obtained by converting the strains according to the result of measurement.

It should be noted that the samples used in the measurement may be obtained by disassembling the electronic device 100. Therefore, the sample of the flexible element FE and the sample of the supporting element SE may respectively include a portion of other layers adhered to the samples. However, since the proportion of the thicknesses of the other layers adhered to the sample is relatively small, the influence of the other layers on the measuring results of the first Young's modulus E1 of the flexible element FE and the second Young's modulus E2 of the supporting elements SE may be neglected.

According to the present embodiment, by making the first Young's modulus E1 of the flexible element FE and the second Young's modulus E2 of the supporting elements SE meet the above-mentioned equation (1), the supporting effect of the supporting elements SE to the electronic elements of the electronic device 100 may be improved under the condition that the influence of the supporting elements SE on the flexibility of the electronic device 100 is reduced, thereby improving the reliability or yield of the electronic device 100. Specifically, when the ratio of the second Young's modulus E2 to the first Young's modulus E1 is less than 100, the second Young's modulus E2 may be excessive small, such that the supporting layer cannot effectively serve as the carrier substrate to provide support during the manufacturing process of the electronic device 100. In contrast, when the ratio of the second Young's modulus E2 to the first Young's modulus E1 is greater than 250, the first Young's modulus E1 may be excessive small, such that the circuit layer CL, the light emitting units LU, and the like may not be easily disposed on the flexible element FE.

As shown in FIG. 1, the electronic device 100 may optionally include an elastic element EM, wherein the elastic element EM may be disposed under the supporting elements SE (for example, the first supporting element SE1 and the second supporting element SE2). Specifically, the elastic element EM disposed under the supporting elements SE may cover those supporting elements SE and may be filled into the space SP of the supporting structure SS. That is, the supporting elements SE may be disposed between the flexible element FE and the elastic element EM, but not limited thereto. The elastic element EM may for example include any suitable elastic material, such as polyurethane (PU), polydimethylsiloxane (PDMS), silicone, but not limited thereto. By disposing the elastic element EM under the supporting elements SE, the planarization effect of the bottom surface of the electronic device 100 may be provided. According to the present embodiment, the elastic element EM may have a third Young's modulus E3, and the second Young's modulus E2 of the supporting elements SE and the third Young's modulus E3 of the elastic element EM may meet the following equation (2):

$$400 < E 2 / E 3 < 8000 \qquad ( 2 )$$

For example, any suitable material having the Young's modulus (that is, the third Young's modulus E3) between 0.01 GPa and 0.2 GPa may be selected as the material of the elastic element EM, and glass may be selected as the material of the supporting elements SE, that is, the second Young's modulus E2 may be 71.7 GPa, but not limited thereto. In other embodiments, the elastic element EM and the supporting elements SE may include any suitable material, such that the second Young's modulus E2 and the third Young's modulus E3 meet the equation (2) mentioned above. In some embodiments, the ratio of the second Young's modulus E2 to the third Young's modulus E3 may be between 500 and 7500 (that is, 500<E2/E3<7500). In some embodiments, the ratio of the second Young's modulus E2 to the third Young's modulus E3 may be between 600 and 7000 (that is, 600<E2/E3<7000).

The third Young's modulus E3 of the elastic element EM may be measured through the above-mentioned method, which will not be redundantly described. By making the second Young's modulus E2 and the third Young's modulus E3 meet the equation (2) mentioned above, the reliability or yield of the electronic device 100 may be improved under the condition that the planarization effect of the bottom surface of the electronic device 100 is provided. Specifically, when the ratio of the second Young's modulus E2 to the third Young's modulus E3 is less than 400, the second Young's modulus E2 may be excessive small, such that the supporting layer cannot effectively serve as the carrier substrate to provide support during the manufacturing process of the electronic device 100. In contrast, when the ratio of the second Young's modulus E2 to the third Young's modulus E3 is greater than 8000, the difference between the second Young's modulus E2 and the third Young's modulus E3 may be excessive great, such that the possibility of separation of the elastic element EM and the supporting elements SE during the deformation of the electronic device 100 may increase.

According to the present embodiment, a portion of the flexible element FE overlapped with the space SP may have a first thickness T1, another portion of the flexible element FE overlapped with a supporting element SE (for example, the first supporting element SE1, but not limited thereto) may have a second thickness T2, and the supporting element SE (for example, the first supporting element SE1, but not limited thereto) may have a third thickness T3, wherein the first thickness T1, the second thickness T2 and the third thickness T3 meet the following equation (3):

$$0.05 \leq ( T 2 + T 3 ) / T 1 \leq 0.5 \qquad ( 3 )$$

Specifically, the portion of the flexible element FE overlapped with the space SP may be the bridge portions BP, and the another portion of the flexible element FE overlapped with the supporting elements SE may be the island portions IP. In other words, the first thickness T1 may be the thickness of the bridge portion BP, and the second thickness T2 may be the thickness of the island portion IP. The bottom of the first thickness T1 may be counted at the position where the space SP starts to exist, and the bottom of the third thickness T3 may be counted at the bottom surface of the supporting element SE, but not limited thereto. In some embodiments, the supporting element SE may include a multi-layer structure, and the third thickness T3 may be obtained by measuring the thickness of one or more layers of the supporting element SE. In the present embodiment, the second thickness T2 and the third thickness T3 may respectively be measured in the middle regions of the island portion IP and the supporting element SE. Specifically, the island portion IP may be divided into a left region LR1, a right region RR1 and a middle region MR1 located between the left region LR1 and the right region RR1, wherein the left region LR1, the right region RR1 and the middle region MR1 have substantially the same range, and the second thickness T2 may be measured in the middle region MR1 of the island portion IP. In addition, the supporting element SE may be divided into a left region LR2, a right region RR2 and a middle region MR2 located between the left region LR2 and the right region RR2, wherein the left region LR2, the right region RR2 and the middle region MR2 have substantially the same range, and the third thickness T3 may be measured in the middle region MR2 of the supporting element SE. It should be noted that the thicknesses of the supporting elements SE of the electronic device 100 may be the same or different, and the present embodiment is not limited thereto.

According to the present embodiment, by making the first thickness T1, the second thickness T2 and the third thickness T3 meet the above-mentioned relation, the reliability or yield of the electronic device 100 may be improved. Specifically, when the value of (T2+T3)/T1 is excessive small (for example, less than 0.05, but not limited thereto), the second thickness T2 of the flexible element FE may be excessive small, such that the circuit layer CL and/or the light emitting units LU may not be easily disposed on the flexible element FE, or breakage of the flexible element FE may occur when the circuit layer CL and/or the light emitting units LU are being disposed on the flexible element FE. When the value of (T2+T3)/T1 is excessive great (for example, greater than 0.5, but not limited thereto), the supporting elements SE cannot effectively serve as the carrier substrate to provide support during the manufacturing process of the electronic device 100, thereby affecting the yield of the electronic device 100. In addition, in the present embodiment, the first thickness T1 may be greater than or equal to 100 micrometers, but not limited thereto.

It should be noted that the relation between the first thickness T1, the second thickness T2 and the third thickness T3 is not limited to the contents mentioned above. In some embodiments, the first thickness T1, the second thickness T2 and the third thickness T3 may meet the following equation (4):

$$0.05 \leq ( T 2 + T 3 ) / T 1 \leq 5 \qquad ( 4 )$$

In some embodiments, the first thickness T1, the second thickness T2 and the third thickness T3 may meet the following equation (5):

$$0.1 \leq ( T 2 + T 3 ) / T 1 \leq 3 \qquad ( 5 )$$

According to the present embodiment, an outline of the supporting elements SE (such as the first supporting element SE1, the second supporting element SE2, and the like) may have a curved shape. “The outline of the supporting element SE” described here may be the outline in a cross-sectional view, the outline in a top view and/or the outline obtained by observing the supporting element SE in any direction. The outline in a cross-sectional view of the supporting element SE may refer to FIG. 1, and the outline in a top view of the supporting element SE may refer to FIG. 3, but not limited thereto. For example, as shown in FIG. 1 and FIG. 3, at least a portion of the outline in a cross-sectional view of the supporting element SE and at least a portion of the outline in a top view of the supporting element SE may include curved edges AE, but not limited thereto. In some embodiments, the outline in a top view of the supporting element SE may be a circle, an oval or any suitable curved shape. By making the outline of the supporting element SE include the curved shape, when the supporting elements SE collide with each other due to deformation of the electronic device 100, the possibility of scratching or damage to the supporting elements SE may be reduced, thereby improving the reliability of the electronic device 100.

As shown in FIG. 1, the supporting element SE may have a portion PO1, wherein the portion PO1 may be defined as the portion of the supporting element SE which the outline thereof is the curved shape. In other words, the portion PO1 (or the outline thereof) of the supporting element SE has the curved shape. According to the present embodiment, the portion PO1 of the supporting element SE may have a fourth thickness T4, and the ratio of the fourth thickness T4 of the portion PO1 to the third thickness T3 of the supporting element SE may meet the following formula (6):

$$0.05 < T 4 / T 3 < 0.5 \qquad ( 6 )$$

In the present embodiment, the fourth thickness T4 of the portion PO1 may be defined as the vertical distance from one of the curve-starting points of the curved shape of the outline in a cross-sectional view of the supporting element SE to the bottom surface of the supporting element SE. For example, in the outline in a cross-sectional view of the supporting element SE shown in FIG. 1, the point P5 may be the left starting point of the curved shape of the outline in a cross-sectional view, a horizontal extending line HL (for example, parallel to the bottom surface SF2 of the supporting element SE) may pass through the point P5, and the fourth thickness T4 of the portion PO1 may be the distance from the horizontal extending line HL to the bottom surface SF2 of the supporting element SE, but not limited thereto. In other embodiments, the fourth thickness T4 may be defined as the distance from a horizontal extending line passing through a right starting point of the curved shape of the outline in a cross-sectional view of the supporting element SE to the bottom surface SF2 of the supporting element SE. The ratio of the fourth thickness T4 to the third thickness T3 mentioned above may indicate the proportion of the portion PO1 in the supporting element SE. According to the present embodiment, by making the ratio of the fourth thickness T4 to the third thickness T3 in the above-mentioned range, the reliability of the supporting element SE may be improved. Specifically, when the ratio of the fourth thickness T4 to the third thickness T3 is excessive small (for example, less than 0.05, but not limited thereto), the proportion of the portion PO1 in the supporting element SE is excessive small, and the possibility of scratching or damage to the supporting elements SE may increase when the electronic device 100 is deformed. In contrast, when the ratio of the fourth thickness T4 to the third thickness T3 is excessive large (for example, greater than 0.5, but not limited thereto), damage to the supporting element SE due to excessive stress on the supporting element SE may occur when treatment is performed on the supporting element SE to form the portion PO1.

It should be noted that the range of the ratio of the fourth thickness T4 to the third thickness T3 is not limited to the contents mentioned above. In some embodiments, the ratio of the fourth thickness T4 to the third thickness T3 may be greater than 0.1 and less than 0.5 (that is, 0.1<T4/T3<0.5). In some embodiments, the ratio of the fourth thickness T4 to the third thickness T3 may be greater than 0.15 and less than 0.5 (that is, 0.15<T4/T3<0.5).

According to the present embodiment, in the top view direction of the electronic device 100 (for example, parallel to the direction Z), an area of the flexible element FE may be greater than the total area of the supporting elements SE. In detail, as shown in FIG. 2 and FIG. 3, in the top view direction of the electronic device 100, the flexible element FE may have an area AR1, wherein the area AR1 is the sum of an area A1 of each island portion IP and an area of each bridge portion BP, and the area AR2 may be the sum of an area A2 of each supporting element SE, wherein the area AR1 may be greater than the area AR2. Since the supporting elements SE may not be disposed corresponding to the bridge portions BP, the area AR2 may be less than the area AR1, but not limited thereto. By making the area AR2 of the supporting elements SE less than the area AR1 of the flexible element FE, the flexibility of the electronic device 100 may be improved. Specifically, when the area AR2 is greater than the area AR1, the area of the supporting elements SE may be excessive great, thereby affecting the flexibility of the electronic device 100. Since the area AR1 of the flexible element FE may be greater than the area AR2 (that is, the sum of the areas of the supporting elements SE) of the supporting elements SE, the area AR1 of the flexible element FE may be greater than the area A2 of one of the supporting elements SE (for example, the first supporting element SE1, the second supporting element SE2, and the like).

In addition, as shown in FIG. 2 and FIG. 3, in the top view direction of the electronic device 100, the sum of the areas of the openings OP1 of the flexible structure FS may be an area AR3, and the space SP of the supporting structure SS may have an area AR4, wherein the area AR3 and the area AR4 are greater than 0, and the area AR4 may be greater than the area AR3. The definition of the border BD of the space SP may refer to the contents mentioned above, and will not be redundantly described. Specifically, the area of the region in the border BD may be the sum of the area AR2 of the supporting elements SE and the area AR4 of the space SP, and it can also be the sum of the area AR1 of the flexible element FE and the area AR3 of the openings OP1. Since the area AR1 of the flexible element FE may be greater than the area AR2 of the supporting elements SE, the area AR3 of the openings OP1 of the flexible structure FS may be less than the area AR4 of the space SP of the supporting structure SS.

According to the present embodiment, as shown in FIG. 2 and FIG. 3, in the top view direction of the electronic device 100, the first island portion IP1 of the flexible element FE may have a first area A1, and one of the supporting elements SE (such as the first supporting element SE1, but not limited thereto) may have a second area A2, wherein the first area A1 and the second area A2 may meet the following equation (7):

$$0.6 < A 2 / A 1 < 1.4 \qquad ( 7 )$$

That is, the ratio of the second area A2 to the first area A1 may be greater than 0.6 and less than 1.4. It should be noted that the above-mentioned first area A1 may be the area of one of the island portions IP of the flexible element FE and is not limited to the area of the first island portion IP1. Therefore, the ratio of the second area A2 to the first area A1 may indicate the relationship between the sizes of the area of a supporting element SE and the area of an island portion IP. Specifically, the ratio of the second area A2 to the first area A1 may indicate the relationship between the sizes of the area of a supporting element SE and the area of an island portion IP corresponding to the supporting element SE (or disposed on the supporting element SE). The definition of the region of the island portion IP may refer to the contents mentioned above, and will not be redundantly described. In the present embodiment, the areas of the island portions IP may be the same or different, and the areas of the supporting elements SE may be the same or different. In some embodiments, the ratio of the second area A2 to the first area A1 may be greater than 0.8 and less than 1.2 (that is, 0.8<A2/A1<1.2). In some embodiments, the ratio of the second area A2 to the first area A1 may be greater than 1 and less than 1.2 (that is, 1<A2/A1<1.2), that is, the second area A2 is greater than the first area A1.

According to the present embodiment, by making the ratio of the second area A2 to the first area A1 located in the above-mentioned range, the influence of the supporting elements SE on the flexibility of the electronic device 100 may be reduced under the condition that the supporting effect of the supporting elements SE is not affected. When the ratio of the second area A2 to the first area A1 is excessive small (for example, less than 0.6), the second area A2 of the supporting element SE may be excessive small, such that the supporting elements SE cannot provide sufficient support. When the ratio of the second area A2 to the first area A1 is excessive large (for example, greater than 1.4), the second area A2 of the supporting element SE may be excessive large, and the flexibility of the electronic device 100 may be affected.

In addition, in the present embodiment, a supporting element SE may have a projection on the island portion IP to which the supporting element SE corresponds, and the projection may be located in the island portion IP. For example, as shown in FIG. 1 and FIG. 2, the first supporting element SE1 may be overlapped with the first island portion IP1, and the first supporting element SE1 may have a projection PR1 on the first island portion IP1, wherein in the top view direction, the projection PR1 may be located in the first island portion IP1, or the projection PR1 may be located in the range of the first island portion IP1, but not limited thereto. Similarly, the second supporting element SE2 may be overlapped with the second island portion IP2, and the second supporting element SE2 may have a projection PR2 on the second island portion IP2, wherein the projection PR2 may be located in the second island portion IP2. In such condition, the area of the first supporting element SE1 (that is, the second area A2 mentioned above) may be less than the area of the first island portion IP1 (that is, the first area A1 mentioned above), and the area of the second supporting element SE2 may be less than the area of the second island portion IP2. In other words, the supporting elements SE of the present embodiment may not be overlapped with the bridge portions BP of the flexible element FE and the openings OP1 of the flexible structure FS. Therefore, the flexibility of the electronic device 100 may be improved.

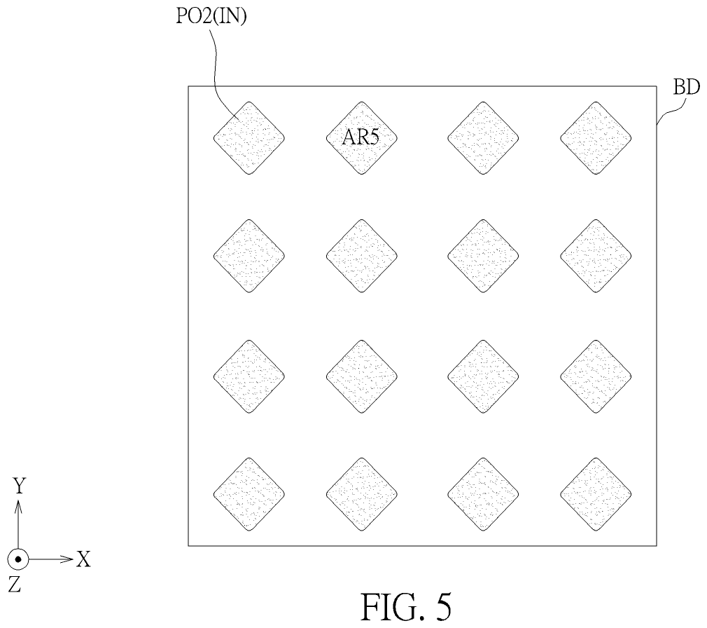

Referring to FIG. 5 as well as FIG. 1, FIG. 5 schematically illustrates a top view of a buffer layer of the electronic device according to the first embodiment of the present disclosure. The buffer layer described here may be the above-mentioned insulating layer IN of the electronic device 100, and the feature thereof may refer to the contents mentioned above, and will not be redundantly described. As shown in FIG. 1, the insulating layer IN may be disposed corresponding to the island portions IP, and therefore, the insulating layer IN may be divided into a plurality of portions PO2 in the top view of the electronic device 100, wherein the portions PO2 may be independent and separated from each other. In addition, the portions PO2 of the insulating layer IN may respectively be corresponding to one of the supporting elements SE. According to the present embodiment, one of the portions PO2 may have an area AR5, and the area AR5 and the second area A2 of the supporting element SE may meet the following formula (8):

$$0.8 < AR 5 / A 2 < 1.2 \qquad ( 8 )$$

That is, the ratio of the area AR5 of the portion PO2 of the insulating layer IN to the second area A2 of the supporting element SE may be greater than 0.8 and less than 1.2. The ratio of the area AR5 to the second area A2 may indicate the relationship between the area of a portion PO2 of the insulating layer IN and the area of a supporting element SE. In the present embodiment, the area AR5 of the portion PO2 of the insulating layer IN may be defined as the area of the bottom surface of the portion PO2 or the area of the outline of the portion PO2 in a top view, but not limited thereto. In some embodiments, the ratio of the area AR5 to the second area A2 may be greater than 0.9 and less than 1.2 (that is, 0.9<AR5/A2<1.2). In some embodiments, the ratio of the area AR5 to the second area A2 may be greater than 1 and less than 1.2 (that is, 1<AR5/A2<1.2). In addition, in the present embodiment, since the portions PO2 of the insulating layer IN are disposed on the island portions IP, the area AR5 of the portion PO2 of the insulating layer IN may not be greater than the first area A1 of the island portion IP of the flexible element FE (that is, AR5≤A1).

According to the present embodiment, by making the ratio of the area AR5 to the second area A2 in the above-mentioned range, the supporting effect of the supporting elements SE and/or the flexibility of the electronic device 100 may be improved. Specifically, when the ratio of the area AR5 to the second area A2 is excessive small (for example, less than 0.8) or great (for example, greater than 1.2), the supporting elements SE may not provide sufficient support during the manufacturing process of the electronic device 100, or breakage of the insulating layer IN may occur when the electronic device 100 is deformed, thereby affecting the reliability or yield of the electronic device 100.

According to the present disclosure, by making the supporting elements SE disposed corresponding to the island portions IP of the flexible element FE, the supporting effect may be provided by the supporting elements SE, and the manufacturing process of the electronic device 100 may not include the step of peeling the supporting layer from the flexible element FE. Therefore, the damage to the flexible element FE or the breakage of the flexible element FE occurred in the peeling process of the supporting layer may be avoided, thereby improving the yield of the electronic device 100. In addition, through the designs of thicknesses and areas of the above-mentioned layers, the influence of the supporting elements SE on the flexibility of the electronic device 100 may be reduced under the condition that the supporting effect of the supporting elements SE is not affected, thereby improving the performance of the electronic device 100.

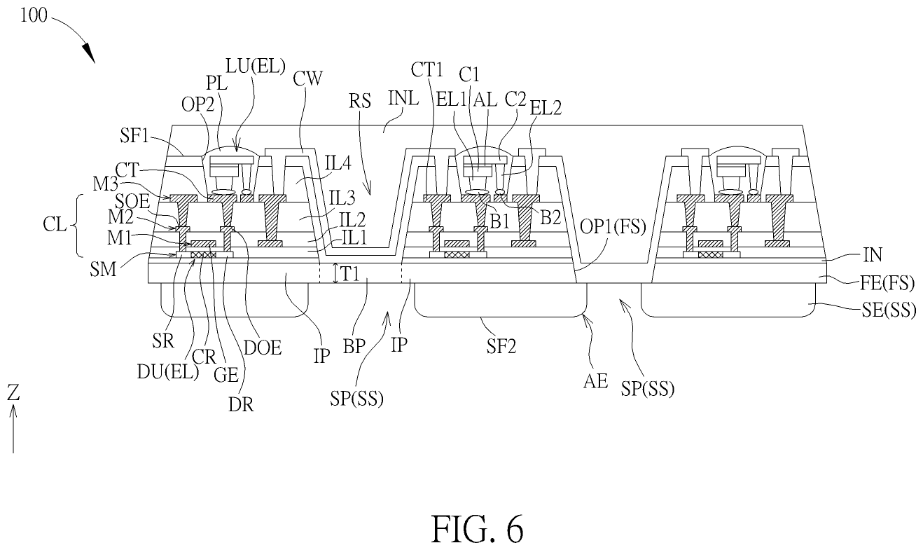

Referring to FIG. 6, FIG. 6 schematically illustrates a cross-sectional view of an electronic device according to a second embodiment of the present disclosure. The features of the elements and/or the layers of the electronic device 200 of the present embodiment may refer to the contents in the above-mentioned first embodiment, and will not be redundantly described. According to the present embodiment, the supporting element SE disposed under the flexible element FE and corresponding to the island portion IP may at least partially overlap the opening OP1 of the flexible structure FS. In other words, the supporting element SE may be protruded from the sidewall of the flexible element FE enclosing the opening OP1 and extend into the region of the opening OP1. In such condition, the projection of a supporting element SE on an island portion IP to which the supporting element SE corresponds may not completely be located in the island portion IP. In addition, since the supporting element SE may be protruded from the sidewall of the flexible element FE, the second area A2 of the supporting element SE may be greater than the first area A1 of the island portion IP, but not limited thereto. It should be noted that the supporting element SE of the present embodiment may not be overlapped with the bridge portion BP of the flexible element FE, such that the influence of the supporting element SE on the flexibility of the electronic device 100 may be reduced.

The manufacturing method of the electronic device of the present disclosure will be detailed in the following.

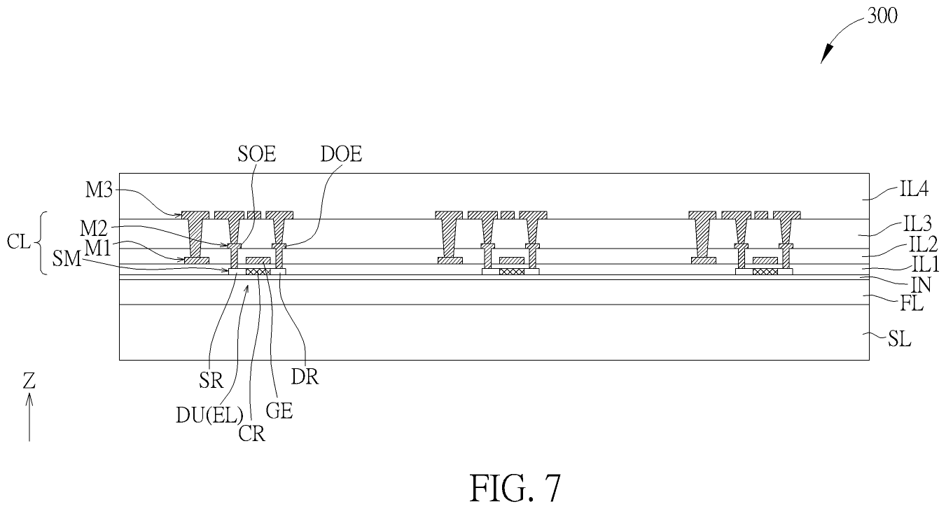

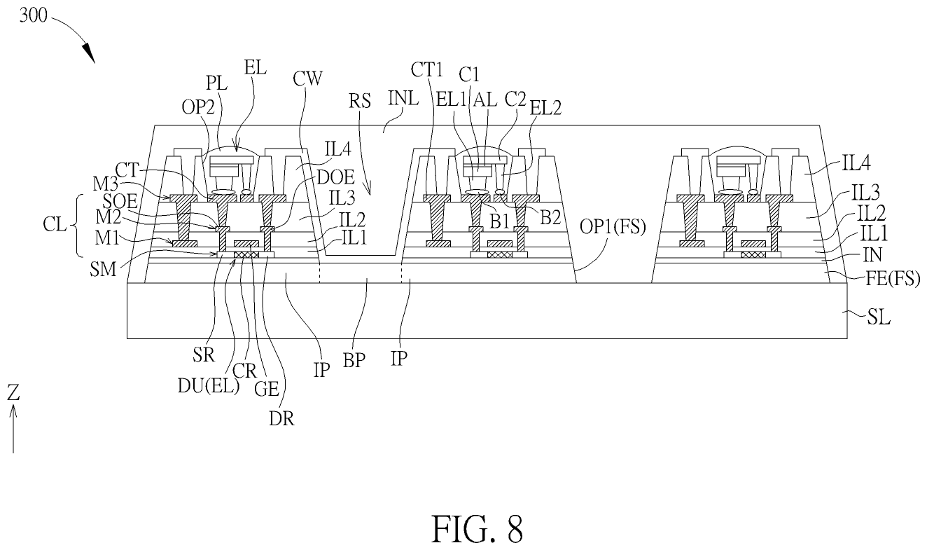

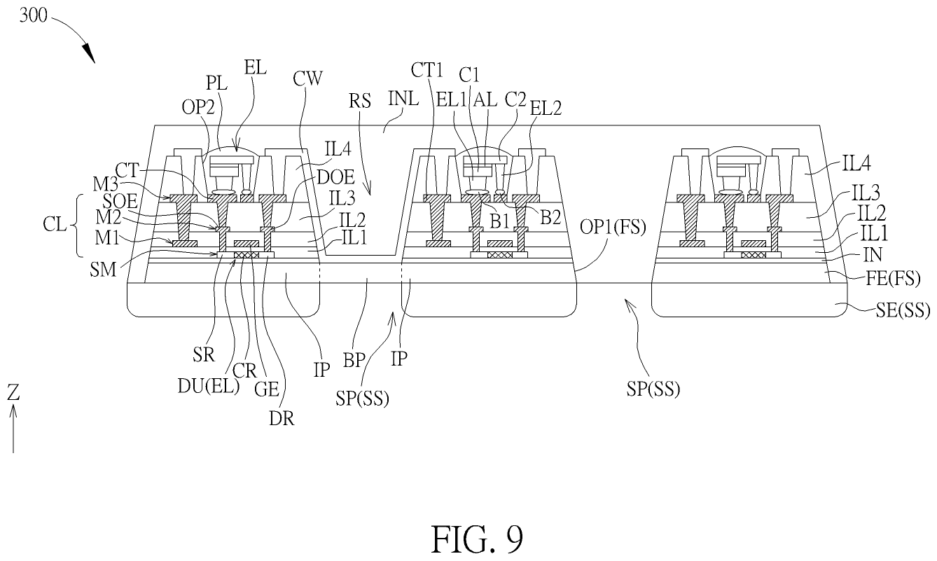

Referring to FIG. 7 to FIG. 9, FIG. 7 to FIG. 9 schematically illustrate the manufacturing process of an electronic device according to a third embodiment of the present disclosure. According to the present embodiment, the manufacturing method of the electronic device 300 may include the following steps:
S102: providing a supporting layer;
S104: forming a flexible layer on the supporting layer;
S106: forming a plurality of electronic units on the flexible layer;
S108: patterning the flexible layer to form the flexible structure; and
S110: patterning the supporting layer to form the supporting structure.

Each of the steps in the manufacturing method of the electronic device 300 will be detailed in the following.

As shown in FIG. 7, the manufacturing method of the electronic device 300 of the present disclosure may include the step S102: providing a supporting layer SL. The supporting layer SL described here is the entire material layer of the supporting elements SE mentioned above. In other words, the supporting layer SL may include the material of the supporting elements SE, and the supporting layer SL may be patterned to form the supporting elements SE in the subsequent process.

The manufacturing method of the electronic device 300 may include the step S104: forming a flexible layer FL on the supporting layer SL. The flexible layer FL described here is the entire material layer of the flexible element FE mentioned above. That is, the flexible layer FL may include the material of the flexible element FE. In other words, an entire flexible layer FL may be disposed on the supporting layer SL at first, and then the flexible layer FL may be patterned to form the flexible element FE in the subsequent process.

The manufacturing method of the electronic device 300 may include the step S106: forming a plurality of electronic units EL on the flexible layer FL. Specifically, after the flexible layer FL is disposed on the supporting layer SL, the above-mentioned elements or layers such as the circuit layer CL, the electronic units EL (shown in FIG. 8), and the like may be formed on the flexible layer FL. The circuit layer CL may be formed on the flexible layer FL completely at first, and the circuit layer CL may be patterned through the subsequent patterning process. For example, as shown in FIG. 7, the insulating layer IN, the semiconductor layer SM, the insulating layer IL1, the conductive layer M1, the insulating layer IL2, the conductive layer M2, the insulating layer IL3, the conductive layer M3 and the insulating layer IL4 may be disposed on the flexible layer FL in sequence, and these layers may form the gate electrode GE, the source electrode SOE, the drain electrode DOE, and the like of the driving unit DU and/or other electronic elements, but not limited thereto. Compared with the electronic device 100 shown in FIG. 1, the electronic device of the present embodiment does not include the insulating layer IL5, but not limited thereto. The details of the layers mentioned above may refer to FIG. 1 and the contents of the above-mentioned first embodiment, and will not be redundantly described. After the circuit layer CL is patterned in the subsequent patterning process, the step of disposing the electronic units EL may be performed, but not limited thereto. It should be noted that the structure shown in FIG. 7 is exemplary, and the present disclosure is not limited thereto.

The manufacturing method of the electronic device 300 may include the step S108: patterning the flexible layer FL to form the flexible structure FS. Specifically, as shown in FIG. 8, after the insulating layer IL4 is disposed, a patterning process may be performed to pattern the circuit layer CL and the flexible layer FL (labeled in FIG. 7). The step of patterning the flexible layer FL may for example include removing a portion of the flexible layer FL to form the openings OP1, thereby forming the flexible structure FS, wherein the flexible structure FS includes the flexible element FE and the plurality of openings OP1. In addition, the patterning process of the circuit layer CL and the flexible layer FL may further include forming the above-mentioned openings OP2 and the recess region (such as the recess region RS), wherein the openings OP2 may be used for disposition of the electronic units EL in the subsequent process, and the recess region may correspond to the bridge portions BP of the flexible element FE and/or the opening OP1 of the flexible structure FS. After the circuit layer CL is patterned, the remaining portions of the circuit layer CL may respectively be disposed corresponding to the island portions IP. In the present embodiment, the step of patterning the flexible layer FL (and the circuit layer CL) may for example include wet etching, dry etching, laser etching or other suitable ways.

After that, the electronic units EL may be disposed in the openings OP2, and a protecting layer PL may be disposed on the electronic units EL. In addition, the step of disposing the conductive wire CW may be performed, wherein the conductive wire CW may extend on the bridge portions BP and electrically connect the electronic units EL (such as the driving units DU) on two adjacent island portions IP. In some embodiments, the step of disposing the electronic units EL may be performed at first, and then the step of disposing the conductive wire CW may be performed. In some embodiments, the step of disposing the conductive wire CW may be performed at first, and then the step of disposing the electronic units EL may be performed. After that, the step of disposing the insulating layer INL may be performed, wherein the insulating layer INL may encapsulate the layers and the electronic elements between the insulating layer INL and the flexible element FE.

The manufacturing method of the electronic device 300 may include the step S110: patterning the supporting layer SL to form the supporting structure SS. Specifically, as shown in FIG. 9, the step of patterning the supporting layer SL (labeled in FIG. 8) may include removing a portion of the supporting layer SL to form the space SP. The step of patterning the supporting layer SL may for example include wet etching, dry etching, laser etching or other suitable ways. After the supporting layer SL is patterned, the supporting structure SS may be formed, wherein the supporting structure SS includes the plurality of supporting elements SE and the space SP. The space SP may correspond to the bridge portions BP of the flexible element FE and the openings OP1 of the flexible structure FS. According to the present t embodiment, in the manufacturing method of the electronic device 300, the flexible layer FL is patterned at first, and then the supporting layer SL is patterned. Therefore, the supporting layer SL may provide support during the manufacturing process of the electronic device 300, thereby improving the yield of the electronic device 300. After the supporting layer SL is patterned to form the supporting structure SS, the electronic device 300 of the present embodiment may be formed.

According to the present embodiment, after the insulating layer INL is disposed, the supporting layer SL may be patterned, and the supporting layer SL may not be removed from the electronic device 300. Through the above-mentioned design, the damage to the flexible element FE or the breakage of the flexible element FE occurred in the peeling process of the supporting layer SL may be avoided, thereby improving the yield of the electronic device 300. In addition, the supporting elements SE formed by patterning the supporting layer SL may provide support to the elements and/or the layers disposed thereon. Moreover, since the supporting elements SE may not be disposed corresponding to the bridge portion BP, the influence of the supporting elements SE on the flexibility of the electronic device 300 may be reduced.

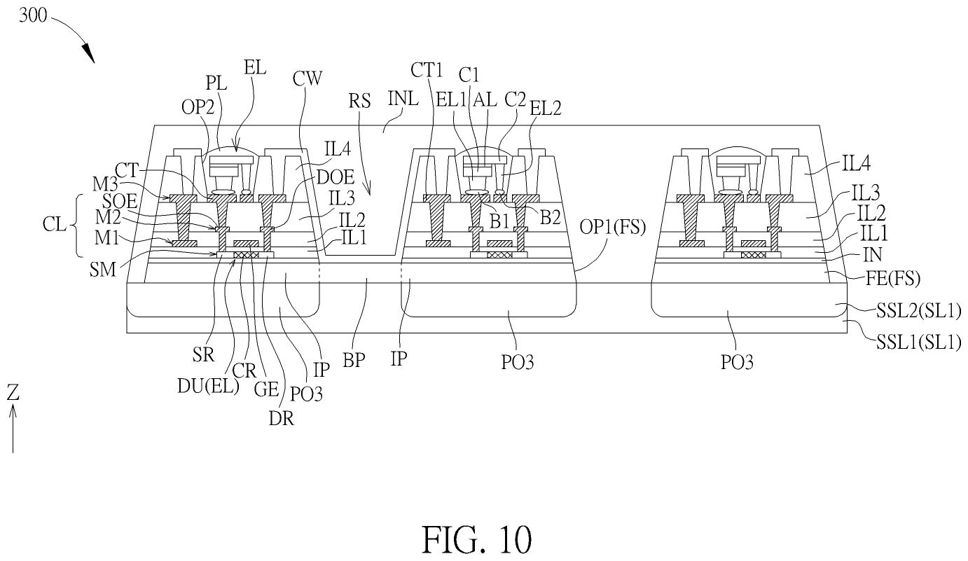

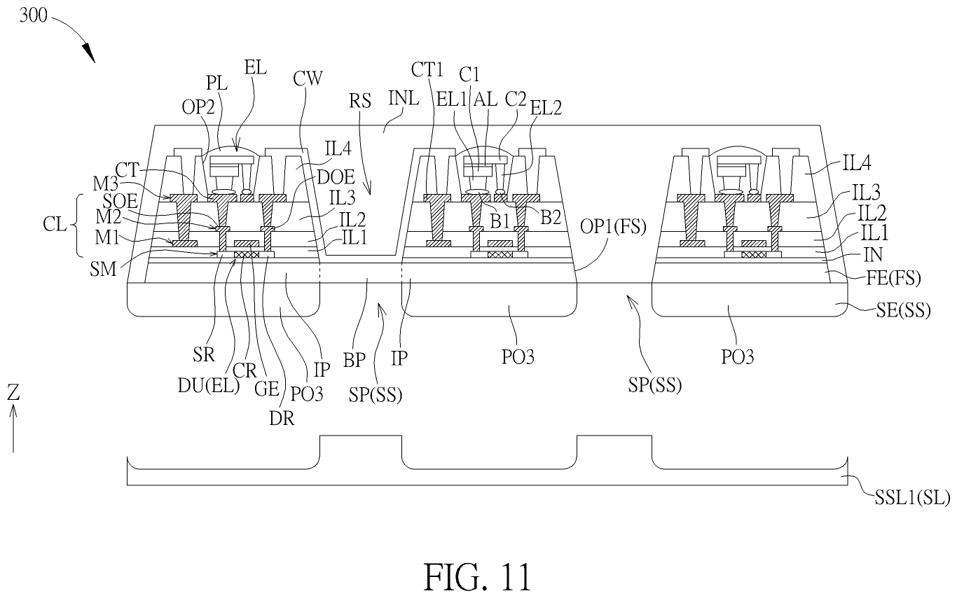

Referring to FIG. 10 and FIG. 11, FIG. 10 and FIG. 11 schematically illustrate the manufacturing process of an electronic device according to a variant embodiment of the third embodiment of the present disclosure. The manufacturing method of the electronic device 300 of the present variant embodiment may refer to the above-mentioned manufacturing method. According to the present variant embodiment, as shown in FIG. 10, when the step S102 (providing a supporting layer SL1) is being performed, the provided supporting layer SL1 may include a first sub supporting layer SSL1 and a second sub supporting layer SSL2, wherein the second sub supporting layer SSL2 may include a plurality of portions PO3 which are independent and separated from each other, and the first sub supporting layer SSL1 may cover the second sub supporting layer SSL2 and be disposed between the portions PO3 of the second sub supporting layer SSL2. In other words, the second sub supporting layer SSL2 may be a patterned layer. The second sub supporting layer SSL2 may be located between the first sub supporting layer SSL1 and the flexible layer FL. The portions PO3 of the second sub supporting layer SSL2 may respectively be disposed corresponding to the predetermined positions where the supporting elements SE are disposed. After that, other steps (such as the step S104 to the step S108) of the above-mentioned manufacturing process may be performed, wherein the detail thereof may refer to the above-mentioned contents, and will not be redundantly described. After that, as shown in FIG. 11, when the step S110 (patterning the supporting layer SL1 to form the supporting structure SS) is being performed, the first sub supporting layer SSL1 may be removed, and the second sub supporting layer SSL2 remained may serve as the supporting elements SE. For example, each of the portions PO3 of the second sub supporting layer SSL2 may serve as a supporting element SE, but not limited thereto. In other words, the supporting layer SL1 may be patterned by removing the first sub supporting layer SSL1. Therefore, the step of patterning the supporting layer SL1 to form the supporting structure SS (that is, the step S110) may include removing the first sub supporting layer SSL1 from the supporting layer SL1. In the present embodiment, since the second sub supporting layer SSL2 may serve as the supporting elements SE, the second sub supporting layer SSL2 may include the material of the supporting elements SE. The material of the first sub supporting layer SSL1 and the material of the second sub supporting layer SSL2 may be the same or different, the present embodiment is not limited thereto. After the first sub supporting layer SSL1 is removed, the electronic device 300 may be formed.

In summary, an electronic device and the manufacturing method thereof are provided by the present disclosure. The electronic device includes a flexible element and supporting elements disposed under the flexible element, wherein the flexible element may be formed by patterning a flexible layer, and the supporting elements may be formed by patterning a supporting layer disposed under the flexible layer. In the manufacturing process of the electronic device, the supporting layer may provide support to the elements or the layers disposed thereon. In addition, since the supporting layer may be patterned and retained in the electronic device, that is, the supporting layer is not removed from the electronic device, the process of peeling the supporting layer is not performed, such that the damage to the flexible element or the breakage of the flexible element occurred in the peeling process of the supporting layer may be avoided, thereby improving the yield of the electronic device. Moreover, through the designs of the disposition position of the supporting elements and the Young's modulus, the thicknesses and the areas of the supporting elements and the flexible element, the influence of the supporting elements on the flexibility of the electronic device may be reduced under the condition that the supporting effect of the supporting elements is not affected. Therefore, the reliability or performance of the electronic device may be improved.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. An electronic device, comprising:
a flexible element;
a plurality of electronic units disposed on the flexible element; and
a first supporting element disposed under the flexible element, wherein the flexible element has a first Young's modulus E1, the first supporting element has a second Young's modulus E2, and the first Young's modulus E1 and the second Young's modulus E2 meet following equation:
$$100 < E 2 / E 1 < 250.$$

2. The electronic device of claim 1, further comprising an elastic element disposed under the first supporting element and having a third Young's modulus E3, wherein the second Young's modulus E2 and the third Young's modulus E3 meet following equation:
$$400 < E 2 / E 3 < 8000.$$

3. The electronic device of claim 1, further comprising a second supporting element disposed under the flexible element and a space between the first supporting element and the second supporting element.

4. The electronic device of claim 3, wherein a portion of the flexible element overlapped with the space has a first thickness T1, another portion of the flexible element overlapped with the first supporting element has a second thickness T2, the first supporting element has a third thickness T3, and the first thickness T1, the second thickness T2 and the third thickness T3 meet following equation:
$$0.05 \leq ( T 2 + T 3 ) / T 1 \leq 0.5 .$$

5. The electronic device of claim 1, wherein an outline of the first supporting element has a curved shape.

6. The electronic device of claim 1, wherein an area of the first supporting element is less than an area of the flexible element.

7. An electronic device, comprising:
a flexible structure having a flexible element and a plurality of openings;
an electronic unit disposed on the flexible element; and
a supporting structure disposed under the flexible structure and having a plurality of supporting elements overlapped with a portion of the flexible element and a space overlapped with the plurality of openings,
wherein an outline of at least one of the supporting elements has a curved shape.

8. The electronic device of claim 7, wherein the flexible element has a first island portion, a second island portion and a bridge portion connecting the first island portion and the second island portion, and the space is overlapped with the bridge portion.

9. The electronic device of claim 8, wherein the supporting structure has a first supporting element and a second supporting element overlapped with the first island portion and the second island portion respectively, the first supporting element has a projection on the first island portion, and the projection is located in the first island portion.

10. The electronic device of claim 8, wherein the first island portion has a first area A1, one of the supporting elements has a second area A2, and the first area A1 and the second area A2 meet following equation:
$$0.6 < A 2 / A 1 < 1.4 .$$

11. The electronic device of claim 8, wherein the bridge portion has a first thickness T1, the first island portion is overlapped with one of the supporting elements and has a second thickness T2, one of the supporting elements has a third thickness T3, and the first thickness T1, the second thickness T2 and the third thickness T3 meet following equation:
$$0.05 \leq ( T 2 + T 3 ) / T 1 \leq 0.5 .$$

12. The electronic device of claim 7, wherein one of the supporting elements has a thickness T3, the one of the supporting elements has a portion which has the curved shape, the portion has another thickness T4, and the thickness T3 and the another thickness T4 meet following equation:
$$0.05 < T 4 / T 3 < 0.5 .$$

13. The electronic device of claim 7, wherein the flexible element has a first Young's modulus E1, the at least one of the supporting elements has a second Young's modulus E2, and the first Young's modulus E1 is less than the second Young's modulus.

14. The electronic device of claim 13, wherein the first Young's modulus E1 and the second Young's modulus E2 meet following equation:
$$100 < E 2 / E 1 < 250.$$

15. The electronic device of claim 7, wherein an area of the openings is less than an area of the space.

16. A method for manufacturing an electronic device, comprising following steps:
providing a supporting layer;
forming a flexible layer on the supporting layer;
forming a plurality of electronic units on the flexible layer;
patterning the flexible layer to form a flexible structure, wherein the flexible structure has a flexible element and a plurality of openings; and
patterning the supporting layer to form a supporting structure after the step of patterning the flexible layer, wherein the supporting structure has a plurality of supporting elements and a space.

17. The method for manufacturing the electronic device of claim 16, wherein the step of patterning the flexible layer comprises wet etching, dry etching or lacer etching.

18. The method for manufacturing the electronic device of claim 16, wherein the supporting layer comprises a first sub supporting layer and a second sub supporting layer disposed between the first sub supporting layer and the flexible layer.

19. The method for manufacturing the electronic device of claim 18, further comprising:
removing the first sub supporting layer in the step of patterning the supporting layer.

20. The method for manufacturing the electronic device of claim 16, wherein the plurality of supporting elements are overlapped with a portion of the flexible element, and the space is overlapped with the plurality of openings.
